(19) United States
(12) Patent Application Publication
(10) Pub. No.: US 2018/0213644 A1
(43) Pub. Date: Jul. 26, 2018

(54) PRINTED WIRING BOARD

(71) Applicant: IBIDEN CO., LTD., Ogaki-shi (JP)

(72) Inventors: Hiroyasu Noto, Ogaki (JP); Yoshinori Takenaka, Ogaki (JP)

(73) Assignee: IBIDEN CO., LTD., Ogaki-shi (JP)

(21) Appl. No.: 15/880,670

(22) Filed: Jan. 26, 2018

(30) Foreign Application Priority Data
Jan. 26, 2017 (JP) 2017-011777

(51) Int. Cl. H05K 1/11; H05K 1/03

(52) U.S. Cl. CPC H05K 1/113; H05K 1/0373; H05K 2201/09827; H01L 23/49838; H05K 2201/0257; H05K 2201/0939; H05K 2201/068; H05K 2201/0266

(57) ABSTRACT

A printed wiring board includes an interlayer resin insulating layer including resin and inorganic particles, a via conductor formed through the insulating layer, a first conductor layer formed on the first surface of the insulating layer and including a land portion of the via conductor on the first surface, and a second conductor layer formed on second surface of the insulating layer and connected to bottom of the via conductor. The bottom of the via conductor has diameter of 20 to 35 μm, the first conductor layer has thickness of 3 to 12 μm, the insulating layer has thickness of 1 to 15 μm, the second conductor layer has thickness of 1 to 12 μm, and the second conductor and insulating layers are formed such that T1/T2 is 0.06 to 7.00 where T1 represents the thickness of the second conductor layer, and T2 represents the thickness of the insulating layer.

### CROSS-REFERENCE TO RELATED APPLICATIONS

The present application is based upon and claims the benefit of priority to Japanese Patent Application No. 2017-011777, filed Jan. 26, 2017, the entire contents of which are incorporated herein by reference.

### BACKGROUND OF THE INVENTION

### Field of the Invention

The present invention relates to a printed wiring board formed by laminating an interlayer resin insulating layer.

### Description of Background Art

Japanese Patent Laid-Open Publication No. 2015-115335 describes a coreless printed wiring board formed by buildup-laminating an interlayer resin insulating layer in which a via conductor is formed. The entire contents of this publication are incorporated herein by reference.

### SUMMARY OF THE INVENTION

According to one aspect of the present invention, a printed wiring board includes an interlayer resin insulating layer including resin and inorganic particles, a via conductor formed in the interlayer resin insulating layer such that the via conductor penetrates through the interlayer resin insulating layer and has a land portion formed on a first surface of the interlayer resin insulating layer, a first conductor layer formed on the first surface of the interlayer resin insulating layer such that the first conductor layer includes the land portion of the via conductor formed on the first surface of the interlayer resin insulating layer, and a second conductor layer formed on a second surface of the interlayer resin insulating layer on the opposite side with respect to the first surface such that the second conductor layer is connected to a bottom portion of the via conductor. The bottom portion of the via conductor has a diameter in a range of 20 to 35 μm, the first conductor layer has a thickness in a range of 3 to 12 μm, the interlayer resin insulating layer has a thickness in a range of 1 to 15 μm, the second conductor layer has a thickness in a range of 1 to 12 μm, and the second conductor layer and the interlayer resin insulating layer are formed such that T1/T2 is in a range of 0.06 to 7.00 where T1 represents the thickness of the second conductor layer, and T2 represents the thickness of the interlayer resin insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view of a printed wiring board according to an embodiment of the present invention;

FIG. 1B is an enlarged view of a via conductor of the printed wiring board according to the embodiment in FIG. 1;

FIG. 1C is an enlarged view of a via conductor of a printed wiring board according to another embodiment of the present invention; and

FIG. 1D is an enlarged view of a via conductor of a printed wiring board according to a reference example.

### DETAILED DESCRIPTION OF THE EMBODIMENTS

Embodiments will now be described with reference to the accompanying drawings, wherein like reference numerals designate corresponding or identical elements throughout the various drawings.

### Reference Example

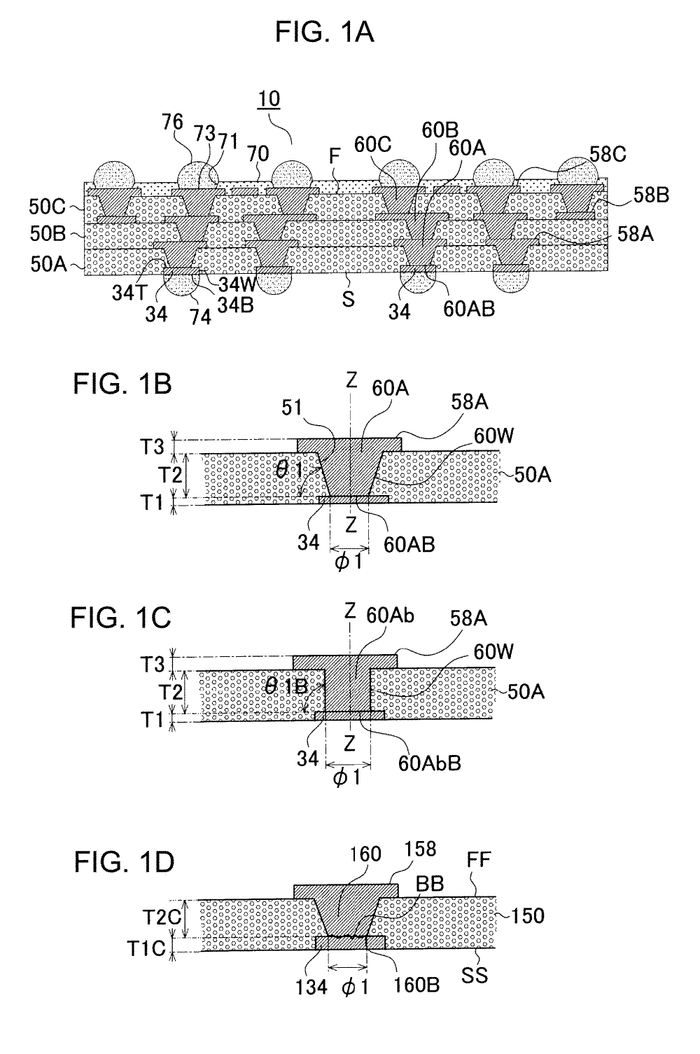

FIG. 1D is an enlarged view of a via conductor of a printed wiring board according to a reference example.

A resin insulating layer 150 has a primary surface (FF) and a secondary surface (SS). A fourth conductor layer 134 embedded in the resin insulating layer 150 is formed on the secondary surface (SS) side, and a third conductor layer 158 is formed on the primary surface (FF) side. The third conductor layer 158 and the fourth conductor layer 134 are connected to each other via a via conductor 160 that penetrates the resin insulating layer 150. The resin insulating layer 150 is formed of a resin that does not contain inorganic fibers but contains ultra-small inorganic filler particles. The inorganic filler particles have a size (average filler particle diameter) of 0.05-1.0 μm and a maximum diameter of 2.0 μm. An amount of the inorganic filler is 35-75 wt %. The resin insulating layer 150 has a thickness (T2C) of 5 μm; the fourth conductor layer 134 has a thickness (T1C) of 12.5 μm; and a bottom part (160B) of the via conductor 160 has a diameter (φ1) of 30 μm. In the printed wiring board of the reference example, a thermal expansion coefficient of the resin insulating layer 150 is 35 ppm, and a thermal expansion coefficient of the via conductor 160 is 16 ppm. Due to the thermal expansion coefficient difference between the resin insulating layer and the via conductor, a thermal stress is applied to the via conductor. Further, (the thickness (T1C) of the fourth conductor layer 134)/(the thickness (T2C) of the resin insulating layer 150) is 2.5, and the thickness of the fourth conductor layer is large relative to the thickness of the resin insulating layer 150. Therefore, when a thermal stress due to thermal expansion of the interlayer resin insulating layer is applied, the fourth conductor layer 134 connected to the bottom part (160B) of the via conductor 160 is difficult to bend, and thus, when the diameter of the bottom part (160B) of the via conductor 160 is reduced to 30 μm, a break (BB) is likely to occur between the bottom part of the via conductor and the fourth conductor layer 134.

### Embodiment

FIG. 1A illustrates a printed wiring board 10 according to an embodiment of the present invention.

The printed wiring board 10 has a first surface (F) and a second surface (S) that is on an opposite side of the first surface, and includes three resin insulating layers including an uppermost resin insulating layer (interlayer resin insulating layer) (50C), a second resin insulating layer (interlayer resin insulating layer) (50B) and a first resin insulating layer (interlayer resin insulating layer) (50A). The uppermost resin insulating layer (50C), the second resin insulating layer (50B) and the first resin insulating layer (50A) are each formed by buildup-laminating a resin film. On the second surface (S) side of the first resin insulating layer (50A), a second conductor layer 34 forming a second pad is formed. A side surface (34W) and an upper surface (34T) of the second conductor layer 34 are embedded in the third resin insulating layer, and only a bottom surface (34B) of the second conductor layer 34 is exposed. A solder bump 74 is formed on the bottom surface (34B) of the second conductor layer 34 forming the second pad. A first conductor layer (58A) is formed on the first surface side of the first resin insulating layer (50A). The second conductor layer 34 and the first conductor layer (58A) are connected via a via conductor (60A) penetrating the first resin insulating layer (50A). A bottom part (60AB) of the via conductor (60A) is connected to the second conductor layer 34. A conductor layer (58B) is formed on the first surface side of the second resin insulating layer (50B). The first conductor layer (58A) and the conductor layer (58B) are connected via a via conductor (60B) penetrating the second resin insulating layer (50B). An uppermost conductor layer (58C) is formed on the first surface side of the uppermost resin insulating layer (50C). The conductor layer (58B) and the uppermost conductor layer (58C) are connected via a via conductor (60C) penetrating the uppermost resin insulating layer (50C). A solder resist layer 70 is formed on the uppermost resin insulating layer (50C) and the uppermost conductor layer (58C). The uppermost conductor layer (58 C) exposed from an opening 71 of the solder resist layer 70 forms a pad 73 for mounting an electronic component. A solder bump 76 for mounting an electronic component is formed on the pad 73 for mounting an electronic component. An electronic component such as an IC chip (not illustrated in the drawings) is mounted via the solder bump 76 for mounting an electronic component.

As each of the resin insulating layers (50A, 50B, 50C), for example, an ABF (Ajinomoto Build-up Film, manufactured by Ajinomoto Fine-Techno Co., Ltd.) can be used. The resin insulating layers (50A, 50B, 50C) are each formed of a resin that does not contain inorganic fibers but contains ultra-small inorganic filler particles. Specifically, the resin insulating layers (50A, 50B, 50C) each include an epoxy-base resin, a polymer-based resin, and a curing agent. The inorganic filler particles have a size (average filler particle diameter) of 0.05-1.0 μm and a maximum diameter of 2.0 μm. An amount of the inorganic filler is 35-75 wt %. The resin insulating layer (50A) of the embodiment contains nano-sized ultra-small inorganic filler particles and thus has a higher viscosity as compared to a resin insulating layer of the same inorganic filler amount (35-75 wt %) containing larger-sized inorganic filler particles, and, when a small diameter opening is formed using laser in order to form a small diameter via, residues containing inorganic filler particles are likely to remain around the opening. A thickness (T2) of the resin insulating layer (50A) is 10 μm, preferably 1-15 μm. Here, the thickness of the resin insulating layer (50A) is an insulating interval of the resin insulating layer, and is a distance from a surface of the second conductor layer 34 to the first conductor layer (58A).

FIG. 1B is an enlarged view of the via conductor (60A) of the printed wiring board of the embodiment.

The via conductor (60A) is formed by filling a truncated conical opening 51, which is formed in the first resin insulating layer 50 and is decreased in diameter toward the second surface (S) side, with plating. A thickness (T3) of the first conductor layer (58A) is 10 μm, preferably 3-12 μm. A thickness (T1) of the second conductor layer 34 is 5 μm, preferably 1-12 μm. The thickness (T1) of the second conductor layer 34 is smaller than the thickness (T3) of the first conductor layer (58A). The diameter (φ1) of the bottom part (60AB) of the via conductor (60A) is 30 μm, preferably 20-35 μm. (The thickness (T1) of the second conductor layer)/(the thickness (T2) of the resin insulating layer) is desirably 0.06-7.00. An angle (θ1) formed by a side wall (60W) of the via conductor 60 and the second conductor layer 34 in a plane along a conical axis Z-Z of the truncated conical via conductor (plane containing the axis Z-Z) is desirably 80-90 degrees. FIG. 1C illustrates another example in which an angle (θ1B) formed by the side wall (60W) of the via conductor 60 and the second conductor layer 34 is 90 degrees. When the angle formed by the side wall (60W) of the via conductor 60 and the second conductor layer 34 is less than 80 degrees, a stress applied to the via conductor (60A) is likely to concentrate on the bottom part (60AB) of the via conductor, and, due to a thermal stress, a break is likely to occur between the bottom part (60AB) of the via conductor and the second conductor layer 34.

As described above, the resin insulating layer of the embodiment contains nano-sized ultra-small inorganic filler particles and thus has a higher viscosity as compared to a resin insulating layer of the same inorganic filler amount (35-75 wt %) containing larger-sized inorganic filler particles, and, when the small diameter opening 51 is formed in order to form the small diameter via (60A), residues containing inorganic filler particles are likely to remain around the opening. Further, the thermal expansion coefficient of the resin insulating layer (50A) is 35 ppm, and the thermal expansion coefficient of via conductor (60A) is 16 ppm. Due to the thermal expansion coefficient difference between the resin insulating layer and the via conductor, a thermal stress is applied to the via conductor (60A) during reflow for mounting an electronic component.

In the printed wiring board of the embodiment, the thickness (T1) of the second conductor layer 34 is smaller than the thickness (T3) of the first conductor layer (58A). The thickness (T2) of the resin insulating layer (50A) is 1-15 μm, and the thickness (T1) of the second conductor layer is 1-12 μm. Further, (the thickness (T1) of the second conductor layer)/(the thickness (T2) of the resin insulating layer) is 0.06-7.00, and the thickness (T1) of the second conductor layer 34 is small relative to the thickness (T2) of the resin insulating layer (50A). Therefore, when a thermal stress due to thermal expansion of the resin insulating layer (50A) is applied, the second conductor layer 34 connected to the bottom part (60AB) of the via conductor is easy to bend, and thus, even when the diameter (φ1) of the bottom part (60AB) of the via conductor (60A) is reduced to 20-35 μm, and further, residues containing inorganic filler particles remain around the opening 51 for forming a via in the resin insulating layer containing ultra-small inorganic particles, a break is unlikely to occur between the bottom part (60AB) of the via conductor and the second conductor layer 34. Therefore, connection reliability of the via conductor is high.

In Japanese Patent Laid-Open Publication No. 2015-115335, due to a difference between a thermal expansion coefficient of a conductor layer and a thermal expansion coefficient of the interlayer resin insulating layer, in a case where the via conductor has a small diameter, when a thermal stress is applied, a crack develops between a bottom part of the via conductor and the conductor layer connected to the bottom part, and a break occurs between the bottom part of the via conductor and the conductor layer.

A printed wiring board according to an embodiment of the present invention includes: an interlayer resin insulating layer that is formed of a resin containing inorganic particles and has a first surface and a second surface that is on an opposite side of the first surface; a via conductor that penetrates the interlayer resin insulating layer; a first conductor layer that is formed on the first surface of the interlayer resin insulating layer and includes a land of the via conductor; and a second conductor layer that is formed on the second surface of the interlayer resin insulating layer and is connected to a bottom part of the via conductor. Then, the bottom part of the via conductor has a diameter of 20-35 μm; the first conductor layer has a thickness of 3-12 μm; the interlayer resin insulating layer has a thickness (T2) of 1-15 μm; the second conductor layer has a thickness (T1) of 1-7 μm; and (the thickness (T1) of the second conductor layer)/(the thickness (T2) of the interlayer resin insulating layer) is 0.06-7.00.

According to an embodiment of the present invention, the thickness of the second conductor layer is small relative to the thickness of the interlayer resin insulating layer. Therefore, when a thermal stress due to thermal expansion of the interlayer resin insulating layer is applied, the second conductor layer connected to the bottom part of the via conductor is easy to bend, and thus, even when the diameter of the via conductor is reduced, a break is unlikely to occur between the bottom part of the via conductor and the second conductor layer. Therefore, connection reliability of the via conductor is high.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an interlayer resin insulating layer comprising resin and inorganic particles;
a via conductor formed in the interlayer resin insulating layer such that the via conductor penetrates through the interlayer resin insulating layer and has a land portion formed on a first surface of the interlayer resin insulating layer;
a first conductor layer formed on the first surface of the interlayer resin insulating layer such that the first conductor layer includes the land portion of the via conductor formed on the first surface of the interlayer resin insulating layer; and
a second conductor layer formed on a second surface of the interlayer resin insulating layer on an opposite side with respect to the first surface such that the second conductor layer is connected to a bottom portion of the via conductor,
wherein the bottom portion of the via conductor has a diameter in a range of 20 to 35 μm, the first conductor layer has a thickness in a range of 3 to 12 μm, the interlayer resin insulating layer has a thickness in a range of 1 to 15 μm, the second conductor layer has a thickness in a range of 1 to 12 μm, and the second conductor layer and the interlayer resin insulating layer are formed such that T1/T2 is in a range of 0.06 to 7.00 where T1 represents the thickness of the second conductor layer, and T2 represents the thickness of the interlayer resin insulating layer.

2. A printed wiring board according to claim 1, wherein the interlayer resin insulating layer is formed such that an amount of the inorganic particles in the interlayer resin insulating layer is in a range of 35 to 75 wt %.

3. A printed wiring board according to claim 2, wherein the interlayer resin insulating layer is formed such that the inorganic particles in the interlayer resin insulating layer has an average particle diameter in a range of 0.05 to 1.0 μm and a maximum diameter of 2.0 μm.

4. A printed wiring board according to claim 1, wherein the first conductor layer and the second conductor layer is formed such that the thickness of the second conductor layer is smaller than the thickness of the first conductor layer.

5. A printed wiring board according to claim 1, wherein the via conductor is formed such that the via conductor has a side wall forming an angle θ1 in a range of 80 to 90 degrees with respect to a plane of the second conductor layer.

6. A printed wiring board according to claim 1, wherein the interlayer resin insulating layer is formed such that the inorganic particles in the interlayer resin insulating layer has an average particle diameter in a range of 0.05 to 1.0 μm and a maximum diameter of 2.0 μm.

7. A printed wiring board according to claim 2, wherein the first conductor layer and the second conductor layer is formed such that the thickness of the second conductor layer is smaller than the thickness of the first conductor layer.

8. A printed wiring board according to claim 2, wherein the via conductor is formed such that the via conductor has a side wall forming an angle θ1 in a range of 80 to 90 degrees with respect to a plane of the second conductor layer.

9. A printed wiring board according to claim 3, wherein the first conductor layer and the second conductor layer is formed such that the thickness of the second conductor layer is smaller than the thickness of the first conductor layer.

10. A printed wiring board according to claim 3, wherein the via conductor is formed such that the via conductor has a side wall forming an angle θ1 in a range of 80 to 90 degrees with respect to a plane of the second conductor layer.

11. A printed wiring board according to claim 6, wherein the first conductor layer and the second conductor layer is formed such that the thickness of the second conductor layer is smaller than the thickness of the first conductor layer.

12. A printed wiring board according to claim 6, wherein the via conductor is formed such that the via conductor has a side wall forming an angle θ1 in a range of 80 to 90 degrees with respect to a plane of the second conductor layer.

13. A printed wiring board according to claim 4, wherein the first conductor layer and the second conductor layer is formed such that the thickness of the second conductor layer is smaller than the thickness of the first conductor layer.

14. A printed wiring board according to claim 9, wherein the via conductor is formed such that the via conductor has a side wall forming an angle θ1 in a range of 80 to 90 degrees with respect to a plane of the second conductor layer.

15. A printed wiring board according to claim 4, wherein the via conductor is formed such that the via conductor has a side wall forming an angle θ1 in a range of 80 to 90 degrees with respect to a plane of the second conductor layer.

16. A printed wiring board according to claim 1, wherein the thickness of the second conductor layer is in a range of 1 to 7 μm.

17. A printed wiring board according to claim 16, wherein the interlayer resin insulating layer is formed such that an amount of the inorganic particles in the interlayer resin insulating layer is in a range of 35 to 75 wt %.

18. A printed wiring board according to claim 17, wherein the interlayer resin insulating layer is formed such that the inorganic particles in the interlayer resin insulating layer has an average particle diameter in a range of 0.05 to 1.0 μm and a maximum diameter of 2.0 μm.

19. A printed wiring board according to claim 16, wherein the first conductor layer and the second conductor layer is formed such that the thickness of the second conductor layer is smaller than the thickness of the first conductor layer.

20. A printed wiring board according to claim 16, wherein the via conductor is formed such that the via conductor has a side wall forming an angle θ1 in a range of 80 to 90 degrees with respect to a plane of the second conductor layer.
